(19) United States
(12) Patent Application Publication
(10) Pub. No.: US 2026/0367146 A1
(43) Pub. Date: Nov. 19, 2026

(54) Single Port Automated USB Interface Switch

(71) Applicant: Sandisk Technologies, Inc., Milpitas, CA (US)

(72) Inventors: Raghavan NAGARAJAN, Bangalore (IN); Balaji G K, Hosur (IN)

(73) Assignee: Sandisk Technologies, Inc., Milpitas, CA (US)

(21) Appl. No.: 19/206,695

(22) Filed: May 13, 2025

(51) Int. Cl. G01R 31/317; G01R 31/3181

(52) U.S. Cl. CPC G01R 31/31723; G01R 31/31704; G01R 31/3172; G01R 31/3181

(57) ABSTRACT

A multiplexer (Mux) adapter board can be used for design validation testing (DVT) product qualification of universal serial bus (USB) devices. A single USB 4.0 device can be connected to a single port on the board to test multiple USB protocols. Several Mux are used to connect and disconnect lines between a host device and the USB device so that USB 4.0, USB 3.0, and USB 2.0 connections can be tested in the single port. In between testing, the board is power cycled. Using the adapter board and a single USB device in a single USB port ensures less manual plugging and unplugging from multiple USB ports. Furthermore, a single USB port will accomplish what previously involved multiple ports. Thus, the adapter board improves USB testing.

### BACKGROUND OF THE DISCLOSURE

### Field of the Disclosure

Embodiments of the present disclosure generally relate to improved universal serial bus (USB) testing.

### Description of the Related Art

Data storage devices are used to store data for a host device. The host device will often send new data to the controller of the data storage device to be written to a memory device of the data storage device. The host device will also send read commands to the controller to instruct the controller to read data from the memory device and provide the data back to the host device. In many cases, the host device and data storage device are connected through a universal serial bus (USB) port/interface using a USB protocol (i.e., USB 2.0, USB 3.0, or USB 4.0).

During the design validation testing (DVT) product qualification, USB 2.0, USB 3.0 and USB 4.0 interfaces need to be tested to validate the compatibility of USB devices across different generations of ports. To test the interfaces, a USB 4.0 device is physically plugged into a USB 4.0 interface and then physically unplugged after testing. A USB 3.0 device is physically plugged into a USB 3.0 interface and then physically unplugged after testing. A USB 2.0 device is physically plugged into a USB 2.0 interface and then physically unplugged after testing.

Alternatively, a USB 4.0 device can be physically plugged into a USB 4.0 interface and then physically unplugged after testing. The same USB 4.0 device can be physically plugged into a USB 3.0 interface and then physically unplugged after testing. The same USB 4.0 device can be physically plugged into a USB 2.0 interface and then physically unplugged after testing.

Regardless of whether a single USB 4.0 device is used or each of a USB 4.0, USB 3.0, and USB 2.0 device is used, a lot of physical plugging and unplugging occurs, which is inefficient. Therefore, there is a need in the art for improved USB testing.

### SUMMARY OF THE DISCLOSURE

A multiplexer (Mux) adapter board can be used for design validation testing (DVT) product qualification of universal serial bus (USB) devices. A single USB 4.0 device can be connected to a single port on the board to test multiple USB protocols. Several Mux are used to connect and disconnect lines between a host device and the USB device so that USB 4.0, USB 3.0, and USB 2.0 connections can be tested in the single port. In between testing, the board is power cycled. Using the adapter board and a single USB device in a single USB port ensures less manual plugging and unplugging from multiple USB ports. Furthermore, a single USB port will accomplish what previously involved multiple ports. Thus, the adapter board improves USB testing.

In one embodiment, an adapter board comprises: a plurality of (Muxs) each having a first connection point, a second connection point, a third connection point, and a switch; a connector for coupling to a control device; first wiring for connecting to a host device and a testing device; second wiring for connecting to the host device and the testing device; third wiring for connecting the plurality of Muxs to the host device; and fourth wiring for connecting the plurality of Muxs to the testing device.

In another embodiment, an adapter board comprises: a first Mux; a second Mux; a third Mux; and a connector coupled to the first Mux, the second Mux, and the third Mux, wherein the connector is configured receive instructions to perform the following process: detect that a universal serial bus (USB) device is coupled thereto; perform a USB 4.0 test, a USB 3.0 test, or a USB 2.0 test; electrically couple the USB device to a host device through one or more of the first Mux, the second Mux, and the third Mux; and power cycle the adapter board.

In another embodiment, an adapter board comprises: first means to electrically connect and disconnect a testing device to a host device through a configuration channel (CC) line; second means to electrically connect and disconnect the testing device to the host device through a transmission (Tx) and receiving (Rx) line; third means to electrically connect and disconnect the testing device to the host device through a sideband (SB) Tx and Rx line; and a connector coupled to the first means, the second means, and the third means, wherein the connector is configured to: instruct the first means to electrically connect and disconnect the testing device and the host device; instruct the second means to electrically connect and disconnect the testing device and the host device; and instruct the third means to electrically connect and disconnect the testing device and the host device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic block diagram illustrating a storage system in which a data storage device may function as a storage device for a host device, according to certain embodiments.

FIG. 2A is schematic illustration of a multiplexer (Mux) adapter board arch according to one embodiment. FIG. 2B is a schematic illustration of the Mux of FIG. 2A.

FIGS. 3A and 3B collectively are a flowchart illustrating a Mux based test sequence according to one embodiment.

FIG. 4 is a schematic illustration of a testing system according to one embodiment.

FIG. 5 is a flowchart illustrating a testing process according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specifically described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments, and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

A multiplexer (Mux) adapter board can be used for design validation testing (DVT) product qualification of universal serial bus (USB) devices. A single USB 4.0 device can be connected to a single port on the board to test multiple USB protocols. Several Mux are used to connect and disconnect lines between a host device and the USB device so that USB 4.0, USB 3.0, and USB 2.0 connections can be tested in the single port. In between testing, the board is power cycled. Using the adapter board and a single USB device in a single USB port ensures less manual plugging and unplugging from multiple USB ports. Furthermore, a single USB port will accomplish what previously involved multiple ports. Thus, the adapter board improves USB testing.

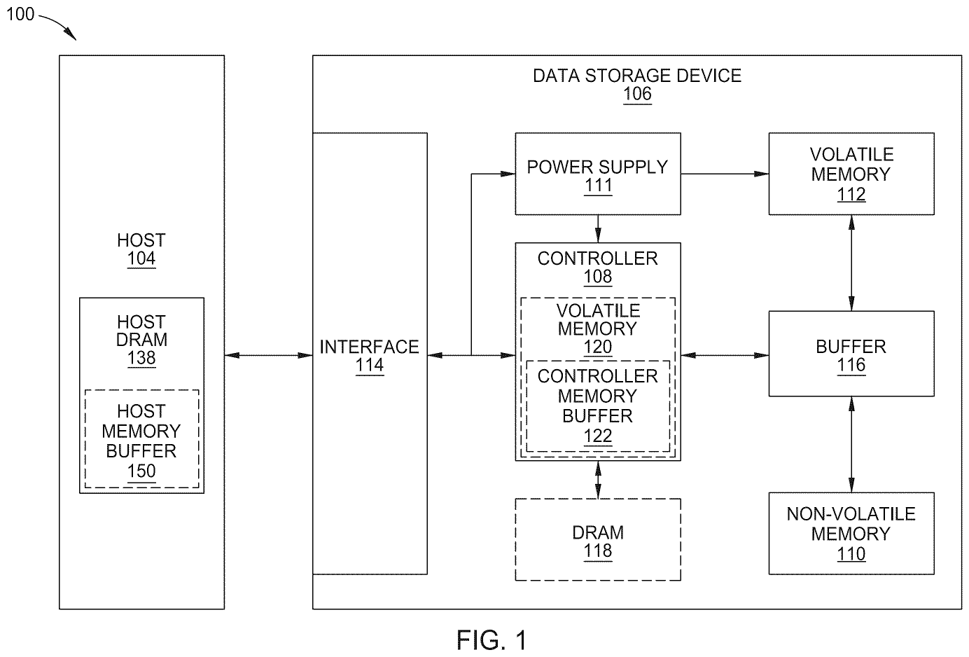

FIG. 1 is a schematic block diagram illustrating a storage system 100 having a data storage device 106 that may function as a storage device for a host device 104, according to certain embodiments. For instance, the host device 104 may utilize a non-volatile memory (NVM) 110 included in data storage device 106 to store and retrieve data. The host device 104 comprises a host dynamic random access memory (DRAM) 138. In some examples, the storage system 100 may include a plurality of storage devices, such as the data storage device 106, which may operate as a storage array. For instance, the storage system 100 may include a plurality of data storage devices 106 configured as a redundant array of inexpensive/independent disks (RAID) that collectively function as a mass storage device for the host device 104.

The host device 104 may store and/or retrieve data to and/or from one or more storage devices, such as the data storage device 106. As illustrated in FIG. 1, the host device 104 may communicate with the data storage device 106 via an interface 114. The host device 104 may comprise any of a wide range of devices, including computer servers, network-attached storage (NAS) units, desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, or other devices capable of sending or receiving data from a data storage device.

The host DRAM 138 may optionally include a host memory buffer (HMB) 150. The HMB 150 is a portion of the host DRAM 138 that is allocated to the data storage device 106 for exclusive use by a controller 108 of the data storage device 106. For example, the controller 108 may store mapping data, buffered commands, logical to physical (L2P) tables, metadata, and the like in the HMB 150. In other words, the HMB 150 may be used by the controller 108 to store data that would normally be stored in a volatile memory 112, a buffer 116, an internal memory of the controller 108, such as static random access memory (SRAM), and the like. In examples where the data storage device 106 does not include a DRAM (i.e., optional DRAM 118), the controller 108 may utilize the HMB 150 as the DRAM of the data storage device 106.

The data storage device 106 includes the controller 108, NVM 110, a power supply 111, volatile memory 112, the interface 114, a write buffer 116, and an optional DRAM 118. In some examples, the data storage device 106 may include additional components not shown in FIG. 1 for the sake of clarity. For example, the data storage device 106 may include a printed circuit board (PCB) to which components of the data storage device 106 are mechanically attached and which includes electrically conductive traces that electrically interconnect components of the data storage device 106 or the like. In some examples, the physical dimensions and connector configurations of the data storage device 106 may conform to one or more standard form factors. Some example standard form factors include, but are not limited to, 3.5″ data storage device (e.g., an HDD or SSD), 2.5″ data storage device, 1.8″ data storage device, peripheral component interconnect (PCI), PCI-extended (PCI-X), PCI Express (PCIe) (e.g., PCIe ×1, ×4, ×8, ×16, PCIe Mini Card, MiniPCI, etc.). In some examples, the data storage device 106 may be directly coupled (e.g., directly soldered or plugged into a connector) to a motherboard of the host device 104.

Interface 114 may include one or both of a data bus for exchanging data with the host device 104 and a control bus for exchanging commands with the host device 104. Interface 114 may operate in accordance with any suitable protocol. For example, the interface 114 may operate in accordance with one or more of the following protocols: advanced technology attachment (ATA) (e.g., serial-ATA (SATA) and parallel-ATA (PATA)), Fibre Channel Protocol (FCP), small computer system interface (SCSI), serially attached SCSI (SAS), PCI, and PCIe, non-volatile memory express (NVMe), OpenCAPI, GenZ, Cache Coherent Interface Accelerator (CCIX), Open Channel SSD (OCSSD), or the like. Interface 114 (e.g., the data bus, the control bus, or both) is electrically connected to the controller 108, providing an electrical connection between the host device 104 and the controller 108, allowing data to be exchanged between the host device 104 and the controller 108. In some examples, the electrical connection of interface 114 may also permit the data storage device 106 to receive power from the host device 104. For example, as illustrated in FIG. 1, the power supply 111 may receive power from the host device 104 via interface 114.

The NVM 110 may include a plurality of memory devices or memory units. NVM 110 may be configured to store and/or retrieve data. For instance, a memory unit of NVM 110 may receive data and a message from controller 108 that instructs the memory unit to store the data. Similarly, the memory unit may receive a message from controller 108 that instructs the memory unit to retrieve data. In some examples, each of the memory units may be referred to as a die. In some examples, the NVM 110 may include a plurality of dies (i.e., a plurality of memory units). In some examples, each memory unit may be configured to store relatively large amounts of data (e.g., 128 MB, 256 MB, 512 MB, 1 GB, 2 GB, 4 GB, 8 GB, 16 GB, 32 GB, 64 GB, 128 GB, 256 GB, 512 GB, 1 TB, etc.).

In some examples, each memory unit may include any type of non-volatile memory devices, such as flash memory devices, phase-change memory (PCM) devices, resistive random-access memory (ReRAM) devices, magneto-resistive random-access memory (MRAM) devices, ferroelectric random-access memory (F-RAM), holographic memory devices, and any other type of non-volatile memory devices.

The NVM 110 may comprise a plurality of flash memory devices or memory units. NVM Flash memory devices may include NAND or NOR-based flash memory devices and may store data based on a charge contained in a floating gate of a transistor for each flash memory cell. In NVM flash memory devices, the flash memory device may be divided into a plurality of dies, where each die of the plurality of dies includes a plurality of physical or logical blocks, which may be further divided into a plurality of pages. Each block of the plurality of blocks within a particular memory device may include a plurality of NVM cells. Rows of NVM cells may be electrically connected using a word line to define a page of a plurality of pages. Respective cells in each of the plurality of pages may be electrically connected to respective bit lines. Furthermore, NVM flash memory devices may be 2D or 3D devices and may be single level cell (SLC), multi-level cell (MLC), triple level cell (TLC), or quad level cell (QLC). The controller 108 may write data to and read data from NVM flash memory devices at the page level and erase data from NVM flash memory devices at the block level.

The power supply 111 may provide power to one or more components of the data storage device 106. When operating in a standard mode, the power supply 111 may provide power to one or more components using power provided by an external device, such as the host device 104. For instance, the power supply 111 may provide power to the one or more components using power received from the host device 104 via interface 114. In some examples, the power supply 111 may include one or more power storage components configured to provide power to the one or more components when operating in a shutdown mode, such as where power ceases to be received from the external device. In this way, the power supply 111 may function as an onboard backup power source. Some examples of the one or more power storage components include, but are not limited to, capacitors, super-capacitors, batteries, and the like. In some examples, the amount of power that may be stored by the one or more power storage components may be a function of the cost and/or the size (e.g., area/volume) of the one or more power storage components. In other words, as the amount of power stored by the one or more power storage components increases, the cost and/or the size of the one or more power storage components also increases.

The volatile memory 112 may be used by controller 108 to store information. Volatile memory 112 may include one or more volatile memory devices. In some examples, controller 108 may use volatile memory 112 as a cache. For instance, controller 108 may store cached information in volatile memory 112 until the cached information is written to the NVM 110. As illustrated in FIG. 1, volatile memory 112 may consume power received from the power supply 111. Examples of volatile memory 112 include, but are not limited to, random-access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)). Likewise, the optional DRAM 118 may be utilized to store mapping data, buffered commands, logical to physical (L2P) tables, metadata, cached data, and the like in the optional DRAM 118. In some examples, the data storage device 106 does not include the optional DRAM 118, such that the data storage device 106 is DRAM-less. In other examples, the data storage device 106 includes the optional DRAM 118.

Controller 108 may manage one or more operations of the data storage device 106. For instance, controller 108 may manage the reading of data from and/or the writing of data to the NVM 110. In some embodiments, when the data storage device 106 receives a write command from the host device 104, the controller 108 may initiate a data storage command to store data to the NVM 110 and monitor the progress of the data storage command. Controller 108 may determine at least one operational characteristic of the storage system 100 and store at least one operational characteristic in the NVM 110. In some embodiments, when the data storage device 106 receives a write command from the host device 104, the controller 108 temporarily stores the data associated with the write command in the internal memory or write buffer 116 before sending the data to the NVM 110. Controller 108 may include circuitry or processors configured to execute programs for operating the data storage device 106.

The controller 108 may include an optional second volatile memory 120. The optional second volatile memory 120 may be similar to the volatile memory 112. For example, the optional second volatile memory 120 may be SRAM. The controller 108 may allocate a portion of the optional second volatile memory to the host device 104 as controller memory buffer (CMB) 122. The CMB 122 may be accessed directly by the host device 104. For example, rather than maintaining one or more submission queues in the host device 104, the host device 104 may utilize the CMB 122 to store the one or more submission queues normally maintained in the host device 104. In other words, the host device 104 may generate commands and store the generated commands, with or without the associated data, in the CMB 122, where the controller 108 accesses the CMB 122 in order to retrieve the stored generated commands and/or associated data.

The current process for USB DVT interface testing involves manual intervention, which presents several challenges and inefficiencies. For example, lab personnel manually connect and disconnect, or vice versa, the USB devices on each compatible port to validate respective speed modes: USB 2.0, USB 3.0 and USB4.0. There are several challenges such as multiple separate ports, manual intervention, and setup disturbance.

The multiple separate ports challenge is that to complete the qualification testing, three different ports for USB 4.0 testing, one USB 2.0, one USB 3.0, and one USB4.0, are used which complicates the setup and increases the chances of errors due to manual intervention. A device is tested in different speed modes to verify that the device functions correctly, but the device cannot switch between the modes without using separate physical ports. During the debugging phase, manually connecting and disconnecting multiple ports for interoperability testing can be highly time-consuming and tedious.

Manual intervention is human resource dependent and involves increased time and effort. Testing personnel manually unplug the USB device from the one port and then plug the USB device into another port which creates a dependency on human resources, leading to inefficiencies, especially during high-volume testing scenarios. Furthermore, there is increased time and effort because each test cycle involves manual disconnection and reconnection of the USB device, which slows down the testing process and increases the potential for human error, such as improper connections or skipping steps.

For setup disturbance, manual plugging and unplugging is an issue, as is inconsistent results. Every time the USB device is manually plugged and unplugged, there is a risk of disturbing the test setup, which may introduce variations in the test results. Manual handling of the hardware can lead to issues such as loose connections or unintentional physical damage, potentially affecting the reliability and consistency of the testing outcomes.

It is desirable to not need manual intervention to perform the testing. As discussed herein, a single port can be used for testing where the single port can test a USB 2.0, USB 3.0, and USB 4.0 connection. There are several limitations to one port testing without having manual intervention.

For a USB 2.0 host device port, when a USB device is connected to a USB 2.0 port, the USB device cannot operate in USB 3.0 mode. Because the USB device communicates through the data lines (i.e., the D− and D+ lines) in USB 2.0 mode, the USB 3.0 lines and USB 4.0 lines are not used, and the USB device is restricted to USB 2.0 speeds which are up to 480 Mbps.

For a USB 3.0 host device port, when connected to a USB 3.0 port, the USB device automatically enumerates and operates in USB 3.0 mode, utilizing the USB 3.0 lines (i.e., the differential pairs or Tx/Rx lines). When using the USB 3.0 lines, the USB 3.0 device's USB 2.0 and USB 4.0 functionality is not operational and thus not tested. Therefore, the USB 3.0 device will operate in USB 3.0.

For a USB 4.0 host device port, when connected to a USB 4.0 port, the USB device automatically enumerates and operates in USB 4.0 mode, utilizing both the USB 3.0 lines (i.e., the differential pairs or Tx/Rx lines) and the USB 4.0 lines (i.e., the side band signal or SB Tx & Rx lines). When using the USB 4.0 lines, the USB 4.0 device's USB 2.0 and USB 3.0 functionality is not operational and thus not tested. Therefore, the USB 4.0 device operate in USB 4.0.

The manual process required to test USB 2.0, USB 3.0 and USB 4.0 interfaces introduces inefficiencies and risks disturbing the test environment. Hence, a hardware based automation approach is proposed to eliminate the human intervention and the need for multiple separate ports, while ensuring accurate and reliable testing of USB 2.0, USB 3.0, and USB 4.0 modes.

The hardware based automation approach involves using an adapter board with a Multiplexer (Mux) between the host device and testing device (i.e., USB device) to automate the switching between USB 2.0 (i.e., using D+/D− lines), USB 3.0 (i.e., using Rx/Tx lines), and USB 4.0 (i.e., using SB Tx/Rx lines) interfaces in a single host device USB 4.0 port. The adapter board allows control of the connection through software on a control device (i.e., PC), eliminating the need for manual intervention.

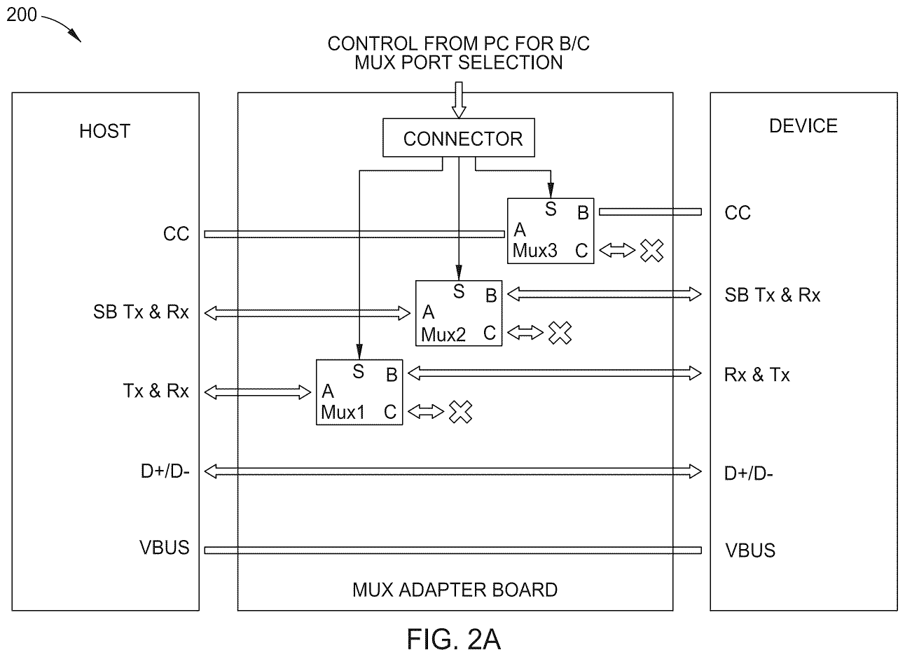

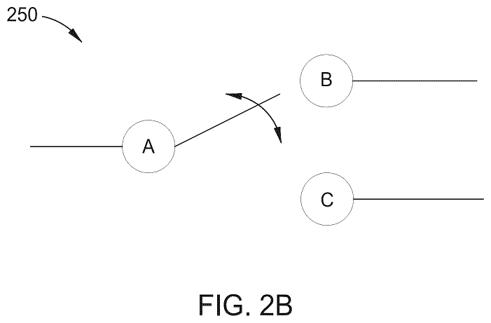

To effectively operate the adapter board, the power supply, control interface, and firmware integration is considered. For the power supply, ensuring that the power to the USB device is off when switching between modes will be taken care by the CC relay. For the control interface, the Mux can be controlled via a USB-to-I2C interface, or similar communication protocol, depending on automation needs. For the FW integration, FW or scripts can trigger the Mux switching during DVT testing. The table below illustrates the interface selection logic truth table and Mux adapter board arch diagram used in FIG. 2A.

| Device Working Mode | Mux 1 S Pin | Mux 2 S Pin | Mux 3 S Pin |
|---|---|---|---|
| USB 4.0 | 1 | 1 | 1 |
| USB 3.0 | 1 | 0 | 1 |
| USB 2.0 | 0 | 0 | 1 |

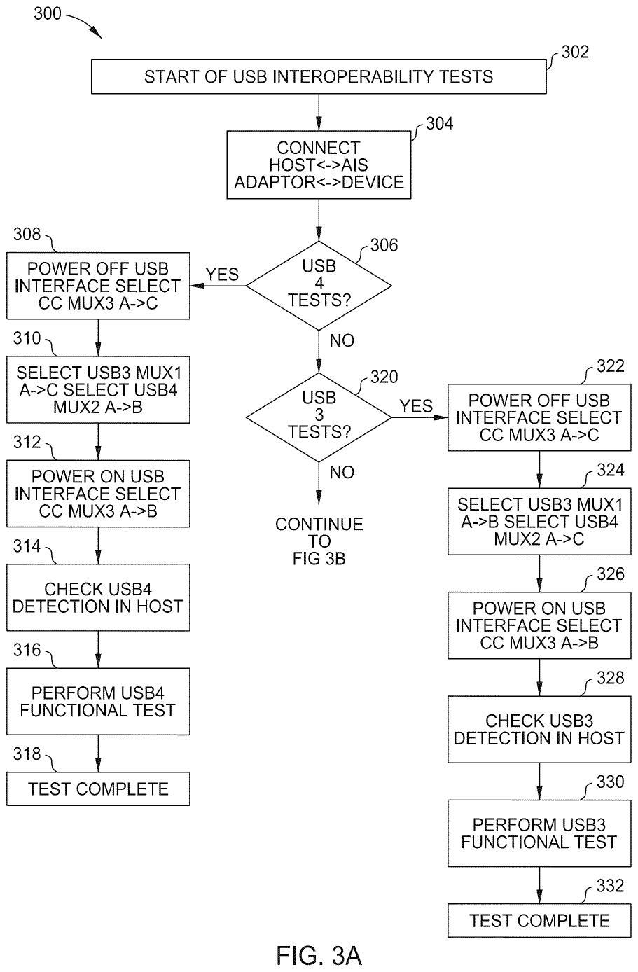

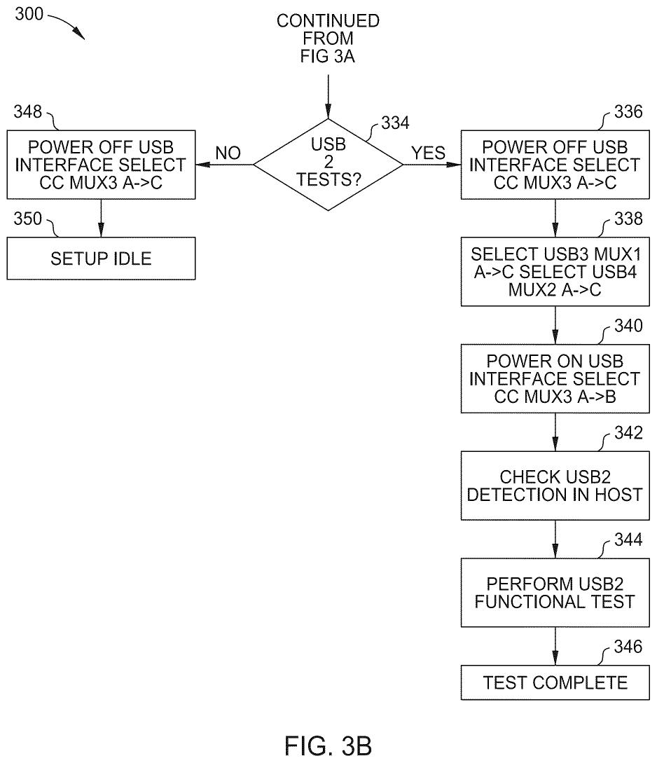

FIG. 2A is schematic illustration 200 of a Mux adapter board arch according to one embodiment. FIG. 2B is a schematic illustration of the Mux 250 of FIG. 2A. The working principle of the Mux adapter board is that the Mux is a switch between A to B or A to C based on control signals from the PC or testing software. There is a USB 2.0/USB 3.0/USB 4.0 connection that establishes different speed mode connections occurs based upon the table above. The Mux can be controlled via software running on the control device (i.e., PC), which allows automated switching between USB 2.0, USB 3.0 and USB 4.0 modes during testing. A custom script or a testing framework can signal the Mux to switch modes to enable running both USB 2.0 and USB 3.0 tests without manual intervention. The Mux based test sequence will follow the flow outlined in FIGS. 3A and 3B to test all USB speeds (i.e., USB 2.0, USB 3.0, and USB 4.0) during a system interoperability test. Using the same port, the USB device can be switched between different USB speeds, and the flow can be fully scripted, allowing tests to be executed remotely. FIGS. 3A and 3B collectively are a flowchart 300 illustrating a Mux based test sequence according to one embodiment.

More specifically with regards to FIGS. 2A, 2B, and 3, the illustration 200 shows a host device, a USB testing device, and a Mux adapter board coupled between the host device and the USB testing device. The USB testing device is simply any USB device and is connected to the Mux adapter board through a USB port of the Mux adapter board. The USB device has a male USB connector that inserts into the female USB port on the Mux adapter board. The Mux adapter board is coupled to the host device in a similar manner such as through some port or connector on the Mux adapter board and a corresponding port or connector on the host device. The host device may be a laptop, personal computer (PC) or any other host device. The Mux adapter board has a connector for connecting to a testing PC or testing system or laboratory PC for controlling the Mux adapter board. A suitable example for the testing PC is a system 100 as shown in FIG. 1.

There are five connections shown in FIG. 2A: the power supply (VBUS), a data (D+/D−) line, a transmission (Tx) & receiving (Rx) line, a side band (SB) Tx & Rx line, and a configuration channel (CC) line. The VBUS and D+/D− lines are always connected when the USB testing device and the host device are connected to the Mux adapter board. However, the Tx&Rx line, the SB Tx&Rx line, and the CC line are not always connected.

More specifically, the Tx&Rx line is always connected to the host device and the USB testing device, but the host device and USB testing device are not always electrically connected because of the first Mux (Mux1). As shown in FIG. 2A, the Tx& Rx line is coupled to the host device and to connection point A of Mux1. The Tx&Rx line is coupled to the USB testing device and connection point B of Mux1. Mux1 also has a connection point C as well as a switching element S. The switching element S cause the connection to switch from connection point B to connection point C so that when the connection is established from connection point A to connection point B, the host device and the USB testing device are electrically coupled through Mux1 as shown in the Mux 250 of FIG. 2B. When the connection is established from connection point A to connection point C, then the host device and the USB testing device are electrically isolated through Mux1 because connection point C is to ground.

Similarly, the SB Tx&Rx line, SB Tx&Rx line is always connected to the host device and the USB testing device, but the host device and USB testing device are not always electrically connected because of the second Mux (Mux2). As shown in FIG. 2A, the SB Tx&Rx line is coupled to the host device and to connection point A of Mux2. The SB Tx&Rx line is coupled to the USB testing device and connection point B of Mux2. Mux2 also has a connection point C as well as a switching element S. The switching element S cause the connection to switch from connection point B to connection point C so that when the connection is established from connection point A to connection point B, the host device and the USB testing device are electrically coupled through Mux2 as shown in the Mux 250 of FIG. 2B. When the connection is established from connection point A to connection point C, then the host device and the USB testing device are electrically isolated through Mux2 because connection point C is to ground.

Finally, the CC line, CC line is always connected to the host device and the USB testing device, but the host device and USB testing device are not always electrically connected because of the third Mux (Mux3). As shown in FIG. 2A, the CC line is coupled to the host device and to connection point A of Mux3. The CC line is coupled to the USB testing device and connection point B of Mux3. Mux3 also has a connection point C as well as a switching element S. The switching element S cause the connection to switch from connection point B to connection point C so that when the connection is established from connection point A to connection point B, the host device and the USB testing device are electrically coupled through Mux3 as shown in the Mux 250 of FIG. 2B. When the connection is established from connection point A to connection point C, then the host device and the USB testing device are electrically isolated through Mux3 because connection point C is to ground.

It is to be understood that the Mux adapter board discussed herein is contemplated to be utilized not only in a testing environment, but also in the field for end users.

The process of operating the Mux adapter board is shown in the flowchart 300. Initially, the USB interoperability tests are started at block 302 and the host device, USB testing device, and Mux adapter board are connected at block 304. A determination is then made at block 306 regarding whether USB 4.0 tests are to be conducted. If USB 4.0 tests are to be conducted, then the USB interface is powered off by selecting the CC line of Mux3 to be connected from connection point A to connection point C at block 308. Thereafter, USB3 is selected by connecting connection point A to connection point C of Mux1, and USB 4 is selected by connecting connection point A to connection point B in Mux 2 at block 310. Thereafter, the USB interface is powered on by connecting connection point A to connection point B on the CC line in Mux3 at block 312. A check for a USB 4.0 detection is then made at block 314 followed by performing the USB 4.0 function test at 316 which will result in a completed test at block 318.

If USB 4.0 tests are not to be conducted at block 306, then the process proceeds to block 320 where a determination is made regarding whether USB 3.0 tests are to be conducted. If USB 3.0 tests are to be conducted, then the USB interface is powered off by selecting the CC line of Mux3 to be connected from connection point A to connection point C at block 322. Thereafter, USB3 is selected by connecting connection point A to connection point B of Mux1, and USB 4 is selected by connecting connection point A to connection point C in Mux2 at block 324. Thereafter, the USB interface is powered on by connecting connection point A to connection point B on the CC line in Mux3 at block 326. A check for a USB 3.0 detection is then made at block 328 followed by performing the USB 3.0 function test at 330 which will result in a completed test at block 332.

If USB 3.0 tests are not to be conducted at block 320, then the process proceeds to block 334 where a determination is made regarding whether USB 2.0 tests are to be conducted. If USB 2.0 tests are to be conducted, then the USB interface is powered off by selecting the CC line of Mux3 to be connected from connection point A to connection point C at block 336. Thereafter, USB3 is selected by connecting connection point A to connection point C of Mux1, and USB 4 is selected by connecting connection point A to connection point C in Mux2 at block 338. Thereafter, the USB interface is powered on by connecting connection point A to connection point B on the CC line in Mux3 at block 340. A check for a USB 2.0 detection is then made at block 342 followed by performing the USB 2.0 function test at 344 which will result in a completed test at block 346. If USB 2.0 tests are not to be conducted at block 334, then the USB interface is powered off by selecting the CC line Mux3 to be connected from connection point A to connection point C at block 348 followed by the Mux adapter board being idle at block 350.

It is to be understood that while the order of USB 4.0, then USB 3.0, then USB 2.0 is the order exemplified in FIGS. 3A and 3B, other orders are contemplated such as USB 4.0, then USB 2.0, and then USB 3.0; or USB 2.0, then USB 3.0, then USB 4.0; of USB 2.0, then USB 4.0, then USB 3.0; or USB 3.0, then USB 4.0, then USB 2.0; or USB 3.0, then USB 2.0, then USB 4.0. In so changing the order, it is to be understood that the “yes” branches of FIGS. 3A and 3B would remain the same, just the order of 306, 320, and 334 would change. Additionally, the “no” branch shown for FIGS. 3A and 3B coming off 334 would be on the last of the order.

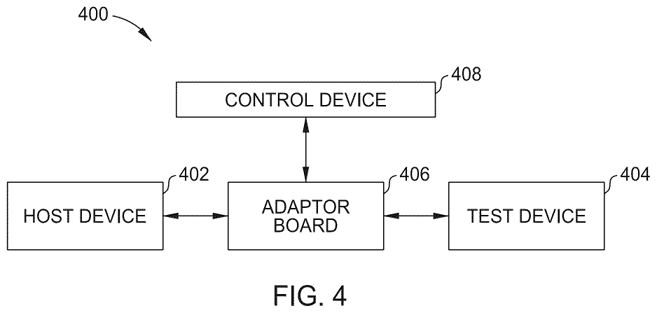

FIG. 4 is a schematic illustration 400 of a testing system according to one embodiment. The illustration shows the host device 402 coupled to the adapter board (e.g., Mux adapter board) 406. The testing device (e.g., USB testing device) 404 is also coupled to the adapter board 406. A control device 408 is also coupled to the adapter board 406. The control device 408 is coupled to the adapter board 406 at a connection point (such as connector as shown in FIG. 2A). The control device 408 may be any control device such as a PC or storage system 100 shown in FIG. 1.

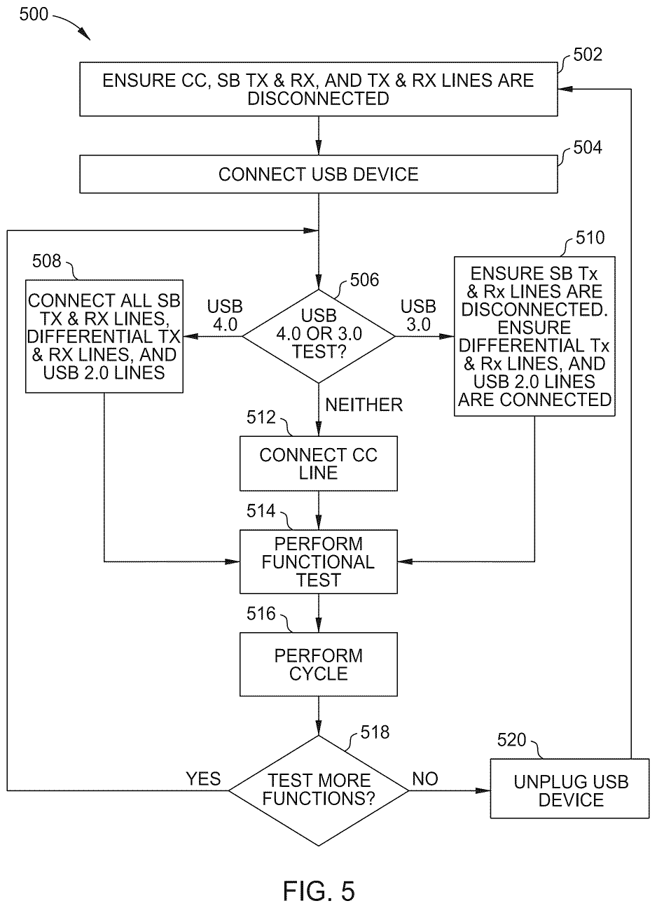

FIG. 5 is a flowchart 500 illustrating a testing process according to one embodiment. Initially, the control device ensures that the CC line, the SB Tx&Rx line, and the Tx&Rx line are disconnected at block 502. To disconnect the CC line, the SB Tx&Rx line, and the Tx&Rx line, the switch in a Mux is moved so that connection point A is connected to connection point C. Thereafter, a USB device to be tested is connected to the Mux adapter board at block 504. A determination is made at block 506 regarding the type of test such as whether a USB 4.0 test, a USB 3.0 test, or a USB 2.0 test is to be performed. If a USB 4.0 test is to be performed, then the SB Tx&Rx line, differential Tx&Rx line, and USB 2.0 lines are all connected at block 508 by moving the switch so that connection point A is coupled to connection point C in the Mux on the SB Tx&Rx line, the Tx&Rx line, and the USB 2.0 line. Thereafter, appropriate functional test is performed at block 514 followed by a power cycle at block 516. Power cycling is a troubleshooting technique where a device is turned off by disconnecting the device from the power source, waiting a short period of time, and then reconnecting the device and turning the device back on, which effectively resets the device to clear temporary glitches and restores functionality.

A determination is then made regarding whether further tests are necessary for the USB testing device currently connected to the Mux adapter board at block 518. If there is further testing, then the process returns to block 506. However, if there is to be no further testing on the USB testing device, then the USB device is unplugged at block 520 and the process returns to block 502.

If the determination at block 506 is that USB 3.0 testing is to be performed, then the Tx&Rx line and USB 2.0 line is connected at block 510 by moving the switch so that connection point A is coupled to connection point C in the Mux on the Tx&Rx line and the USB 2.0 line while ensuring the SB Tx&Rx line is disconnected. The process then proceeds to block 514. If neither USB 4.0 nor USB 3.0 testing it to occur at block 506, then the testing is for USB 2.0 and the process proceeds directly to block 512 where the CC line is connected by moving the switch so that connection point A is coupled to connection point C in the Mux on the CC line.

By using the Mux adapter board discussed herein, manual intervention is reduced and possibly even eliminated because the entire USB testing process becomes automated, with no need to physically unplug and replug the USB device. The Mux enables seamless switching between USB 2.0, USB 3.0 and USB 4.0 modes, allowing for faster and more efficient testing cycles. There is reduced setup disturbance. Because the connection remains stable and the switching is handled through HW, there is no risk of disturbing the setup or causing inconsistent results due to manual handling. There is improved efficiency because using the Mux adapter board allows for quicker testing and improving throughput, especially in high-volume test environments. The resulting Mux adapter board is a single port (for the USB testing device) automated USB interface switch (using the mux and PC connection at the connector) so that the USB testing device can simply be plugged in, controller through the connector to the Mux adapter board, and tested for USB 4.0, USB 3.0, and USB 2.0 without ever needing to be unplugged after the initial plugging in. Thus, using the Mux adapter board discussed herein results in improved USB testing.

In one embodiment, an adapter board comprises: a plurality of Muxs each having a first connection point, a second connection point, a third connection point, and a switch; a connector for coupling to a control device; first wiring for connecting to a host device and a testing device; second wiring for connecting to the host device and the testing device; third wiring for connecting the plurality of Muxs to the host device; and fourth wiring for connecting the plurality of Muxs to the testing device. The plurality of Muxs comprise a first Mux, a second Mux, and a third Mux. The third wiring comprises: a first Tx& Rx line coupled to the first Mux; a first SB Tx&Rx line coupled to the second Mux; and a first configuration channel line coupled to the third Mux. The fourth wiring comprises: a first Tx&Rx line coupled to the first Mux; a first side band SB Tx&Rx line coupled to the second Mux; and a first configuration channel line coupled to the third Mux. The third wiring is connected to the first connection point and wherein the fourth wiring is connected to the second connection point. The third connection point is connected to ground. The switch is coupled to the first connection point and wherein the switch is configured to move between a connection to the second connection point and a connection to the third connection point. The plurality of Muxs are electrically isolated from each other.

In another embodiment, an adapter board comprises: a first Mux; a second Mux; a third Mux; and a connector coupled to the first Mux, the second Mux, and the third Mux, wherein the connector is configured receive instructions to perform the following process: detect that a USB device is coupled thereto; perform a USB 4.0 test, a USB 3.0 test, or a USB 2.0 test; electrically couple the USB device to a host device through one or more of the first Mux, the second Mux, and the third Mux; and power cycle the adapter board. The connector is configured to receive instructions to perform a USB 4.0 test and electrically coupled the USB device to the host device through the second Mux and the third Mux. The USB device and the host device are electrically isolated through the first Mux. The connector is configured to receive instructions to connect the USB device and the host device through the second Mux prior to connecting the USB device and the host device through the third Mux. The connector is configured to receive instructions to perform a USB 3.0 test and electrically coupled the USB device to the host device through the first Mux and the third Mux. The USB device and the host device are electrically isolated through the second Mux. The connector is configured to receive instructions to connect the USB device and the host device through the first Mux prior to connecting the USB device and the host device through the third Mux. The connector is configured to receive instructions to perform a USB 2.0 test and electrically coupled the USB device to the host device through the third Mux. The USB device and the host device are electrically isolated through the first Mux and the second Mux.

In another embodiment, an adapter board comprises: first means to electrically connect and disconnect a testing device to a host device through a CC line; second means to electrically connect and disconnect the testing device to the host device through a Tx&Rx line; third means to electrically connect and disconnect the testing device to the host device through a SB Tx&Rx line; and a connector coupled to the first means, the second means, and the third means, wherein the connector is configured to: instruct the first means to electrically connect and disconnect the testing device and the host device; instruct the second means to electrically connect and disconnect the testing device and the host device; and instruct the third means to electrically connect and disconnect the testing device and the host device. The connector is configured to instruct the second means to electrically connect the testing device and the host device prior to instructing the third means to electrically connect the testing device and the host device, and wherein the connector is configured to maintain the testing device and the host device disconnected through the first means while the second means and the third means are electrically connected. The connector is configured to instruct the first means to electrically connect the testing device and the host device prior to instructing the third means to electrically connect the testing device and the host device, and wherein the connector is configured to maintain the testing device and the host device disconnected through the second means while the first means and the third means are electrically connected.

While the foregoing is directed to embodiments of the present disclosure, other and further embodiments of the disclosure may be devised without departing from the basic scope thereof, and the scope thereof is determined by the claims that follow.

What is claimed is:

1. An adapter board, comprising:
a plurality of multiplexers (Muxs) each having a first connection point, a second connection point, a third connection point, and a switch;
a connector for coupling to a control device;
first wiring for connecting to a host device and a testing device;
second wiring for connecting to the host device and the testing device;
third wiring for connecting the plurality of Muxs to the host device; and
fourth wiring for connecting the plurality of Muxs to the testing device.

2. The adapter board of claim 1, wherein the plurality of Muxs comprise a first Mux, a second Mux, and a third Mux.

3. The adapter board of claim 2, wherein the third wiring comprises:
a first transmission (Tx) and receiving (Rx) line coupled to the first Mux;
a first side band (SB) Tx and Rx line coupled to the second Mux; and
a first configuration channel line coupled to the third Mux.

4. The adapter board of claim 3, wherein the fourth wiring comprises:
a first transmission (Tx) and receiving (Rx) line coupled to the first Mux;
a first side band (SB) Tx and Rx line coupled to the second Mux; and
a first configuration channel line coupled to the third Mux.

5. The adapter board of claim 1, wherein the third wiring is connected to the first connection point and wherein the fourth wiring is connected to the second connection point.

6. The adapter board of claim 5, wherein the third connection point is connected to ground.

7. The adapter board of claim 1, wherein the switch is coupled to the first connection point and wherein the switch is configured to move between a connection to the second connection point and a connection to the third connection point.

8. The adapter board of claim 1, wherein the plurality of Muxs are electrically isolated from each other.

9. An adapter board, comprising:
a first multiplexer (Mux);
a second Mux;
a third Mux; and
a connector coupled to the first Mux, the second Mux, and the third Mux, wherein the connector is configured receive instructions to perform the following process:
detect that a universal serial bus (USB) device is coupled thereto;
perform a USB 4.0 test, a USB 3.0 test, or a USB 2.0 test;
electrically couple the USB device to a host device through one or more of the first Mux, the second Mux, and the third Mux; and
power cycle the adapter board.

10. The adapter board of claim 9, wherein the connector is configured to receive instructions to perform a USB 4.0 test and electrically coupled the USB device to the host device through the second Mux and the third Mux.

11. The adapter board of claim 10, wherein the USB device and the host device are electrically isolated through the first Mux.

12. The adapter board of claim 11, wherein the connector is configured to receive instructions to connect the USB device and the host device through the second Mux prior to connecting the USB device and the host device through the third Mux.

13. The adapter board of claim 9, wherein the connector is configured to receive instructions to perform a USB 3.0 test and electrically coupled the USB device to the host device through the first Mux and the third Mux.

14. The adapter board of claim 13, wherein the USB device and the host device are electrically isolated through the second Mux.

15. The adapter board of claim 14, wherein the connector is configured to receive instructions to connect the USB device and the host device through the first Mux prior to connecting the USB device and the host device through the third Mux.

16. The adapter board of claim 9, wherein the connector is configured to receive instructions to perform a USB 2.0 test and electrically coupled the USB device to the host device through the third Mux.

17. The adapter board of claim 16, wherein the USB device and the host device are electrically isolated through the first Mux and the second Mux.

18. An adapter board, comprising:
first means to electrically connect and disconnect a testing device to a host device through a configuration channel (CC) line;
second means to electrically connect and disconnect the testing device to the host device through a transmission (Tx) and receiving (Rx) line;
third means to electrically connect and disconnect the testing device to the host device through a sideband (SB) Tx and Rx line; and
a connector coupled to the first means, the second means, and the third means, wherein the connector is configured to:
instruct the first means to electrically connect and disconnect the testing device and the host device;
instruct the second means to electrically connect and disconnect the testing device and the host device; and
instruct the third means to electrically connect and disconnect the testing device and the host device.

19. The adapter board of claim 18, wherein the connector is configured to instruct the second means to electrically connect the testing device and the host device prior to instructing the third means to electrically connect the testing device and the host device, and wherein the connector is configured to maintain the testing device and the host device disconnected through the first means while the second means and the third means are electrically connected.

20. The adapter board of claim 18, wherein the connector is configured to instruct the first means to electrically connect the testing device and the host device prior to instructing the third means to electrically connect the testing device and the host device, and wherein the connector is configured to maintain the testing device and the host device disconnected through the second means while the first means and the third means are electrically connected.
